(19) United States
(12) Patent Application Publication
(10) Pub. No.: US 2016/0298228 A1
(43) Pub. Date: Oct. 13, 2016

(54) SOFT-MAGNETIC BASED TARGETS HAVING IMPROVED PASS THROUGH FLUX

(71) Applicant: Tosoh SMD, Inc., Grove City, OH (US)

(72) Inventors: Eugene Y. Ivanov, Grove City, OH (US); Steven Woodward, Columbus, OH (US); Eduardo del Rio, Dublin, OH (US); Christopher M. Jaworski, Grove City, OH (US)

(21) Appl. No.: 15/093,883

(22) Filed: Apr. 8, 2016

Related U.S. Application Data
(60) Provisional application No. 62/145,554, filed on Apr. 10, 2015.

(51) Int. Cl. C23C 14/34; H01J 37/34; B22F 3/14; B22F 3/24; C23C 14/14; B22F 9/08

(52) U.S. Cl. CPC C23C 14/3414; C23C 14/14; B22F 9/082; B22F 3/14; B22F 3/24; H01J 37/3429; B22F 2009/0844; B22F 2003/248; B22F 2301/15; B22F 2301/35

(57) ABSTRACT

Sputter targets and method of producing same having improved pass through flux (PTF). The targets may consist essentially of Fe—Co wherein the Co is predominantly hcp phase. The targets are prepared via powder precursors wherein at least the Co is made by a gas atomization process. This atomization process includes the steps of subjecting liquid Co to the action of dry argon gas and solidifying the liquid into small droplets. After the requisite powders have been sintered, they may be cold worked at temperatures of about 25-422° C.

### CROSS REFERENCE TO RELATED APPLICATION

This application claims the priority benefit of U.S. Provisional Patent Application Ser. No. 62/145,554 filed Apr. 10, 2016.

### FIELD OF INVENTION

The present invention relates to soft-magnetic based target materials which have superior pass through flux properties.

### BACKGROUND OF THE INVENTION

Magnetron sputtering methods are generally used for preparation of the magnetic alloy films, such as Fe—Co, Ni—Pt, Co—Pt etc., films. In these methods, a magnet is disposed behind a target material to leak the magnetic flux region, thus enabling a high-speed coating. For example Fe—Co based materials are desired to provide a high magnetic flux density which is required for the magnetron sputtering. However, in some cases, thin targets must be provided in order to achieve the desired pass through flux (PTF), but these thin targets are quickly consumed during sputtering operations. When targets are thick enough to possess desirable consumption time attributes, the pass through flux is diminished thereby resulting in sputtering failure. The same problem exists for other magnetic alloys.

Cobalt, in the low temperature stable HCP phase, has a large difference in magnetic permeability between magnetic easy [0001] and magnetic hard [101-0] axes. In FCC phase (T>422° C.), there is little difference in magnetic permeability between easy and hard axes. The FCC to HCP transformation upon cooling has been found to be sluggish and incomplete, with a portion of the Cobalt remaining FCC at room temperature. The HCP phase is stable at low temperature, and transforms to FCC above 422° C. To remedy this, in U.S. Pat. No. 6,585,866, it was discovered that cold working cobalt sputtering targets could increase PTF. This is because any remaining FCC Co was transformed to HCP Co. Furthermore, the HCP Co became textured, with preferential orientation of [0001] axis perpendicular to the plane of the target. Texturing the FCC Cobalt will not improve PTF, due to the small difference in magnetic permeability of the different crystallographic orientations.

Tanaka (J. Appl. Phys. 69 1 1991) synthesized Co and FeCo alloys via roll reduction. They found that FeCo alloys containing more than 1.2% Fe have easy axis in-plane at room temperature, whereas FeCo alloys with less than 1.2% Fe have easy axis perpendicular to plane at room temperature. Easy axis in-plane is detrimental to achieving high PTF. Therefore, any FeCo alloy target material with more than 1.2% Fe will have poor PTF. Thus, there is no currently known method to increase the PTF of FeCo alloys to allow for successful sputtering.

### SUMMARY OF THE INVENTION

In accordance with one aspect of the invention, a magnetic target having improved magnetic pass through flux is provided. The target consists essentially of a metal alloy having the formula Me_{(X)}Z_{(100-X)} wherein Me and Z are different, with Me chosen from the group consisting of Fe, Co, and Ni and wherein Z is chosen from the group consisting of Ni, Co and Pt. In certain exemplary embodiments, X is chosen so that it is a number between 1 and 99. In other embodiments, Me is Fe and Z is Co. In other embodiments, Me is Co and Z is Pt, and in other embodiments, Me is Ni and Z is Pt. Other illustrative embodiments include those in which Me is Ni and Z is Co or wherein Me is Fe and Z is Ni.

In other aspects of the invention, a magnetic target is provided that has improved pass through flux. The target is devoid of non-magnetic oxides and non-magnetic silicides and wherein the target comprises a Fe/Co alloy wherein Fe is present in an atomic percent of about 1-99% and wherein the Co is present in an amount of about 99-1% atomic. In other embodiments of the invention, the Co has a hcp crystallographic orientation. In certain embodiments, the Co that is present has both an hcp phase and fcc phase presence. In certain aspects of the invention, the hcp phase present in Co is present in an amount of greater than 50% based upon a combined total of 100% of the hcp and fcc phases. In other exemplary embodiments, the hcp phase content of the Co is greater than 70%.

In other embodiments of the invention, methods are provided for producing a Co—Fe based alloy sputtering target material. The method comprises pressurized sintering of powder compositions wherein the compositions of Fe powder and Co powder are sintered at temperatures of from about 500° C. to 1400° C. and at pressures from 20 MPa to 200 MPa and at a sintering time from about 1 hour to about 10 hours.

In further embodiments, methods are provided for producing a Co—Fe based alloy sputtering target wherein the method comprises pressurized sintering of powdered compositions having a composition represented by the combination of Fe powder and Co powder wherein the Co and Fe powders are both made by Ar gas atomization. In other exemplary embodiments, the Co present is predominantly hexagonal phase Co.

In other embodiments, a Co—Fe based alloy sputtering target material is provided wherein the sintered mass of target material is cold worked at temperatures of between about 25-422° C. to a reduction of thickness between 10 and 60%.

### DESCRIPTION OF THE INVENTION

In certain embodiments, the magnetic targets having improved pass through flux consists essentially of a metal alloy having the formula Me_{(X)}Z_{(100-X)} wherein Me and Z are different, with Me chosen from the group consisting of Fe, Co, and Ni and wherein Z is chosen from the group consisting of Co and Pt. X is a positive number between 0 and 100. Exemplary targets include Fe/Co, Ni/Pt and Co/Pt.

In one embodiment, the inventors have now found that pass through flux can be improved in FeCo based target materials without impairing superior magnetic properties of the film, by adopting an Fe:Co atomic ratio in the range of Fe 10:90 and Co 70:30.

Accordingly, one aspect of the invention provides a soft-magnetic FeCo based target material which has a high PTF and does not require the use of nonmetallic or nonmagnetic elements or alloys.

In some embodiments, the present invention provides a soft-magnetic FeCo based target material made of an FeCo based alloy, wherein the alloy has an Fe:Co atomic ratio in the range of Fe 10:90 to Co 70:30.

In more specific embodiments, the targets are devoid of non magnetic oxides and non magnetic silicides.

In other aspects of the invention, the target are Fe/Co alloy targets, wherein Fe is present (atomic percent) in an amount of about 1-99 wt % and the Co is present in an amount of about 99-1% atomic. In preferred embodiments the Co is hcp phase crystallography and in even more specific embodiments the hcp phase is present, (relative to combined Co hcp and Co fcc=100%), in an amount of greater than 50%, even greater than 70%.

In one aspect of the invention, the target material of the present invention is made of an FeCo based alloy consisting of or consisting essentially of Fe and Co.

The FeCo based alloy used in the present invention comprises Fe and Co as the main constituent elements which form the FeCo based alloy. The Fe:Co atomic ratio ranges from Fe 10:90 to Co 70:30. Within these ranges, it is possible to improve PTF.

According to a preferred aspect of the present invention, the Fe—Co based alloy can comprise 5-50 at. % preferably 5 to 30 at. % of Co wherein the Co is present in the form of hexagonal cobalt phase for improving magnetic field penetration through target material.

Regarding a method for producing the FeCo based alloy of the present invention, vacuum melting and casting are typically employed. However, vacuum melting and casting the FeCo based alloy results in crystal orientation depending on the direction of solidification, thus making it difficult to achieve uniform cast structure in terms of chemical composition. For this reason, in melted and cast Co alloy target materials, a difference in sputter rate depending on the crystal orientation is caused and the magnetic flux penetration through target in the magnetron sputtering process is typically extremely low and varies, resulting in variations in the sputtered film thickness. In view of this, the inventors found that a uniform target material in terms of increased PTF as well as of chemical composition can be achieved by the powder metallurgy process.

The consolidating method employed in the present invention includes any technique that can consolidate a high density target material, such as HIP, hot pressing technique, and the like. The method for producing the powder includes any techniques such as gas atomizing, water atomizing and casting-crushing, but is not limited to these. As described above, the magnetron sputtering technique is typically used for producing soft-magnetic films. The new phenomenon used in this embodiment is that atomized Co powder consists of predominantly hexagonal Co phase which is beneficial for increased PTF. This hexagonal phase is stable and forms at low temperature i.e., less than or equal to 422° C. Melting and casting a Co ingot has been shown to cause a mixture of hexagonal and cubic crystal structure, to the detriment of PTF. However, it has been found in the present invention that Co can be preserved in primarily hexagonal form in the atomization process, which consists of melting pure Co metal, subjecting liquid metal to action of stream of dry argon gas and solidifying into small liquid droplets. Formed cobalt powder is then collected and can be used in further processing.

After the powders have been sintered, the resulting mass may be cold worked at a temperature of between about 25-422° C. to a reduction of thickness between 10 and 60%. The cold worked mass may then be machined or otherwise finished so as to impact the desired target thickness and configuration to it.

### Examples

The present invention will be described below in detail with references to examples.

FeCo based alloys were produced by a gas atomizing technique making separately Fe and Co powders. Then, the particle size of the powder thus produced was classified to obtain powder with particle sizes of 300 μm or less. Then, the obtained powders were mixed for one hour by a V-type mixer to achieve desirable Fe—Co composition by blending appropriate weights of Fe and Co powders.

The powder blend thus produced was charged into a sealed container made of steel. Then, the sealed container was evacuated and vacuum-sealed at an ultimate pressure of 10̂-1 Pa or less. Then, HIP (Hot Isostatic Pressing) was preformed to produce an ingot on condition that the temperature was 1373 K, the pressure was 150 MPa, and the retention time was five hours. Then, the ingot thus produced was subjected to a machining process to obtain target materials each having a final configuration. For evaluation items of the properties of the target materials thus produced, the PTF (pass through flux) was measured, and targets were sputtered to produce FeCo film.

In another embodiment, the powder blend thus produced was charged into a vacuum hot press. Then, hot pressing was performed to produce an ingot on condition that the temperature was 1373 K, the pressure was 20 MPa, and the retention time was three hours. Then, the ingot thus produced was subjected to a machining process to obtain target materials each having a final configuration.

### Magnetic Properties

### Pass Through Flux

Flat specimens each having an outer diameter of 5″, and a thickness of 1-10 mm were made. Then, a PTF was measured for each sample providing PTF/thickness variation. For comparison purposes, cast FeCo and cast/atomized FeCo samples were also produced. The properties of the target materials are shown in Table 1.

TABLE 1
Pass through flux of FeCo alloy for same thickness in range of 5.82 mm.

| | Pass |
|---|---|
| Description | Through Flux |
| Cast into FeCo alloy, then | 3.1% |
| thermomechanically processed | |
| Cast into FeCo alloy, atomized, | 3.3% |
| then hot pressed | |
| Blend of atomized Co and Fe | 4.9% |
| powder, then hot press | |

As shown in Table 1, target material made from the blend of atomized Co and Fe powders, has advantage in higher PTF value compared to cast or cast and atomized samples.

As described above, controlling the atomic ratio of Fe to Co to an Fe:Co range from 10:90 Fe to 70:30 Co makes it possible to produce magnetic FeCo based target material having a high PTF. This enables to achieve significantly beneficial effects of providing sufficient improvement in PTF.

1. A magnetic target having improved magnetic pass through flux, said target consisting essentially of a metal alloy having the formula Me_{(X)}Z_{(100-X)} wherein Me and Z are different, with Me chosen from the group consisting of Fe, Co, and Ni and wherein Z is chosen from the group consisting of Ni, Co and Pt.

2. A magnetic target as recited in claim 1 wherein 1<x<99.

3. A magnetic target as recited in claim 1 wherein Me is Fe and Z is Co.

4. A magnetic target as recited in claim 1 wherein Me is Co and Z is Pt.

5. A magnetic target as recited in claim 1 wherein Me is Ni and Z is Pt.

6. A magnetic target as recited in claim 1 where Me is Ni and Z is Co.

7. A magnetic target as recited in claim 1 where Me is Fe and Z is Ni.

8. A magnetic target having improved pass through flux, said target being devoid of non magnetic oxides and non magnetic silicides, said target comprising a Fe/Co alloy wherein Fe is present in an atomic percent of about 1-99% and said Co is present in an amount of about 99-1% atomic.

9. A magnetic target as recited in claim 8 wherein said Co has a hcp crystallographic orientation.

10. A magnetic target as recited in claim 9 wherein hcp phase Co and fcc phase Co are both present with the provision that said hcp phase Co is present in an amount of greater than 50% based upon a combined total of 100% of said hcp and fcc phases.

11. A magnetic target as recited in claim 10 wherein the amount of hcp phase Co is greater than 70%.

12. A method of producing the Co—Fe based alloy sputtering target material according to claim 8, the method comprising pressurized sintering of powdered composition having a composition represented by combination of Fe powder and Co powder under conditions of sintering temperature of from 500° C. to 1400° C. and pressurizing pressure from 20 MPa to 200 MPa and a sintering time from 1 hour to 10 hours.

13. A method of producing the Co—Fe based alloy sputtering target material according to claim 9 the method comprising pressurized sintering of powdered composition having a composition represented by combination of Fe powder and Co powder where Co and Fe powders are both made by argon gas atomization.

14. A method of producing the Co—Fe based alloy sputtering target material according to claim 13, the method comprising pressurized sintering of powdered composition having a composition represented by combination of Fe powder and Co powder where Co and Fe powders are both made by argon gas atomization and Co is present in predominantly hexagonal phase throughout the target.

15. A method of producing the Co—Fe based alloy sputtering target material according to claim 12 the method further comprising cold working of the sintered mass of target material at a temperature between 25-422° C. to a reduction of thickness between 10 and 60%.
